(19) United States
(12) Patent Application Publication
(10) Pub. No.: US 2017/0263853 A1
(43) Pub. Date: Sep. 14, 2017

(54) SPIN TRANSFER TORQUE MEMORY AND LOGIC DEVICES HAVING AN INTERFACE FOR INDUCING A STRAIN ON A MAGNETIC LAYER THEREIN

(71) Applicant: INTEL CORPORATION, Santa Clara, CA (US)

(72) Inventors: Sasikanth Manipatruni, Portland, OR (US); Anurag Chaudhry, Sunnyvale, CA (US); Dmitri Nikonov, Beaverton, OR (US); David Michalak, Portland, OR (US); Stephen Cea, Hillsboro, OR (US); Ian Young, Portland, OR (US)

(73) Assignee: INTEL CORPORATION, Santa Clara, CA (US)

(21) Appl. No.: 15/329,987

(22) PCT Filed: Sep. 3, 2014
(86) PCT No.: PCT/US2014/053812

§ 371 Date: Jan. 27, 2017

(51) Int. Cl. H01L 43/02; H01L 27/22; H01F 41/30; H01L 43/10; H01F 10/16; H01F 10/32; G11C 11/16; H01L 43/08

(52) U.S. Cl. CPC H01L 43/02; G11C 11/161; H01L 27/228; H01L 43/08; H01L 43/10; H01F 10/16; H01F 10/3222; H01F 41/302

(57) ABSTRACT

The present disclosure relates to the fabrication of spin transfer torque memory devices and spin logic devices, wherein a strain engineered interface is formed within at least one magnet within these devices. In one embodiment, the spin transfer torque memory devices may include a free magnetic layer stack comprising a crystalline magnetic layer abutting a crystalline stressor layer. In another embodiment, the spin logic devices may include an input magnet, an output magnet; wherein at least one of the input magnet and the output magnet comprises a crystalline magnetic layer abutting crystalline stressor layer and/or the crystalline magnetic layer abutting a crystalline spin-coherent channel extending between the input magnet and the output magnet.

### BACKGROUND OF THE INVENTION

Embodiments of the present description generally relate to the field of microelectronic devices, and, more particularly, to spin transfer torque memory and logic devices.

### BACKGROUND

Higher performance, lower cost, increased miniaturization of integrated circuit components, and greater packaging density of integrated circuits are ongoing goals of the microelectronic industry for the fabrication of microelectronic logic and memory devices. Spin devices, such as spin logic and spin memory, can enable a new class of logic and architectures for microelectronic components. However, spin devices suffer from low speed with high switching current operation. Thus, there is an ongoing drive to improve the efficiency of these spin devices.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1a is a schematic diagram illustrating a spin transfer torque memory device in accordance with an embodiment of the present description.

FIG. 1b is a schematic diagram illustrating a spin transfer torque memory device in accordance with another embodiment of the present description.

FIG. 2a is a side view schematic illustrating a magnetic tunneling junction with a free magnetic layer having a magnetic orientation anti-parallel to a fixed magnetic layer in accordance with an embodiment of the present description.

FIG. 2b is a side view schematic illustrating a magnetic tunneling junction with a free magnetic layer having a magnetic orientation parallel to a fixed magnetic layer in accordance with an embodiment of the present description.

FIG. 3 illustrates an oblique schematic of a spin transfer torque memory device, as known in the art.

FIG. 4 illustrates an oblique schematic of a spin transfer torque memory device in accordance with an embodiment of the present description.

FIG. 5 illustrates an oblique schematic of a spin transfer torque memory device in accordance with another embodiment of the present description.

FIG. 6 illustrates an oblique schematic of a spin transfer torque memory device in accordance with yet another embodiment of the present description.

FIG. 7 is a graph of spin current versus switching time with regard to the embodiments of FIGS. 3 and 4.

FIG. 8 is a side view schematic of a spin logic device, as known in the art.

FIG. 9 is a side view schematic of a spin logic device in accordance with an embodiment of the present description.

FIG. 10 illustrates a computing device in accordance with one implementation of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

Embodiments of the present description relate to the fabrication of spin transfer torque memory devices and spin logic devices, wherein a strain engineered interface is formed to abut at least one magnet within these devices. In one embodiment, the spin transfer torque memory devices may include a free magnetic layer stack comprising a crystalline magnetic layer abutting a crystalline stressor layer. In another embodiment, the spin logic devices may include an input magnet, an output magnet; wherein at least one of the input magnet and the output magnet comprises a magnet stack including a crystalline magnetic layer abutting a crystalline stressor layer; and a spin-coherent channel extending between the input magnet and the output magnet. In still another embodiment, the spin logic devices may include an input magnet, an output magnet, a crystalline spin-coherent channel extending between the input magnet and the output magnet, wherein at least one of the input magnet and the output magnet comprises a crystalline magnetic layer abutting the crystalline spin-coherent channel.

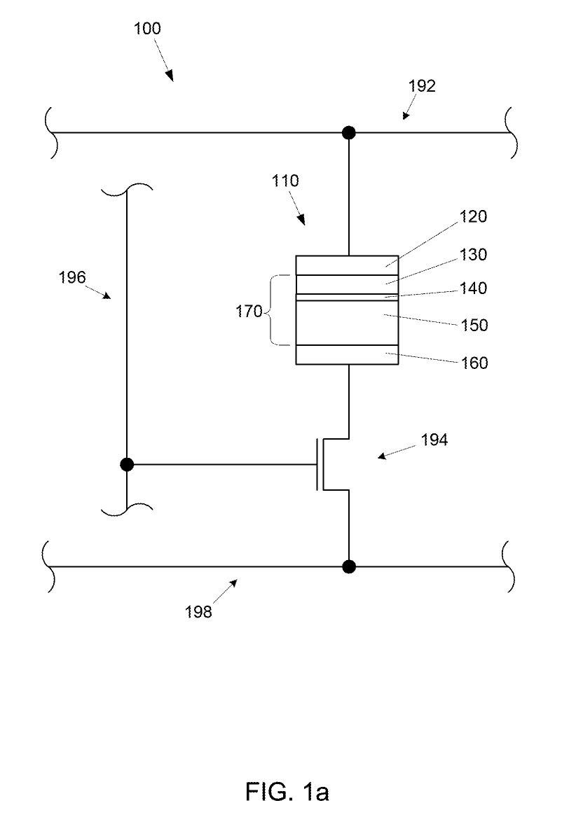

FIG. 1a shows a schematic of a known spin transfer torque memory device 100 which includes a spin transfer torque element 110. The spin transfer torque element 110 may comprise a top contact or free magnetic layer electrode 120 with a free magnetic layer 130 adjacent the free magnetic layer electrode 120, a fixed magnetic layer electrode 160 adjacent a pinned or fixed magnetic layer 150, and a tunneling barrier layer 140 deposed between the free magnetic layer 130 and the fixed magnetic layer 150. The free magnetic layer electrode 120 may be electrically connected to a bit line 192. The fixed magnetic layer electrode 160 may be connected to a transistor 194. The transistor 194 may be connected to a word line 196 and a signal line 198 in a manner that will be understood to those skilled in the art. The spin transfer torque memory device 100 may further include additional read and write circuitry (not shown), a sense amplifier (not shown), a bit line reference (not shown), and the like, as will be understood by those skilled in the art, for the operation of the spin transfer torque memory device 100. It is understood that a plurality of the spin transfer torque memory devices 100 may be operably connected to one another to form a memory array (not shown), wherein the memory array can be incorporated into a non-volatile memory device.

The portion of the spin transfer torque element 110 comprising the free magnetic layer 130, the tunneling barrier layer 140, and the fixed magnetic layer 150 is known as a magnetic tunneling junction 170.

As shown in FIG. 1b, the spin transfer torque memory device 100 may have a reverse orientation, wherein the free magnetic layer electrode 120 may be electrically connected to the transistor 194 and the fixed magnetic layer electrode 160 may be connected to the bit line 192.

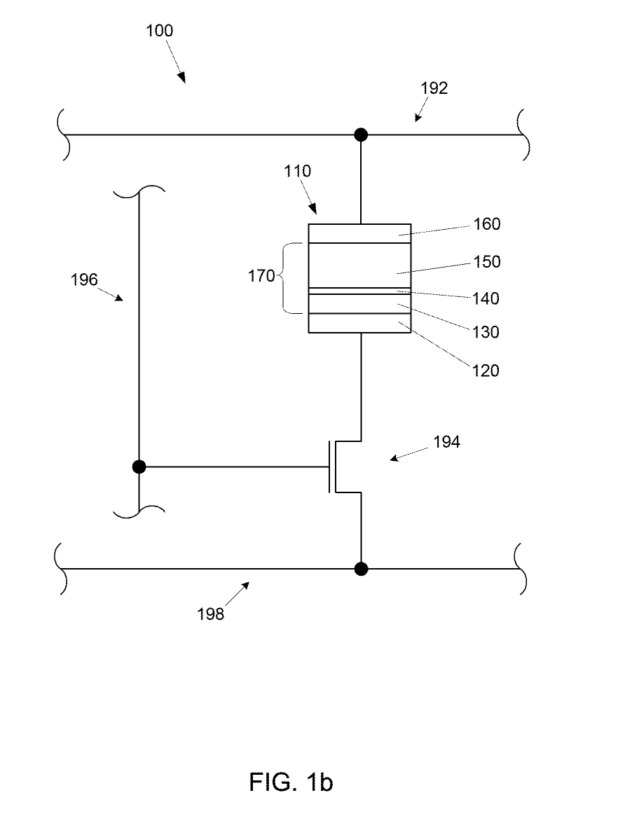

Referring to FIGS. 2a and 2b, the magnetic tunneling junction 170 functions essentially as a resistor, where the resistance of an electrical path through the magnetic tunneling junction 170 may exist in two resistive states, either “high” or “low”, depending on the direction or orientation of magnetization in the free magnetic layer 130 and in the fixed magnetic layer 150. FIG. 2a illustrates a high resistive state, wherein direction of magnetization in the free magnetic layer 130 and the fixed magnetic layer 150 are substantially opposed or anti-parallel with one another. This is illustrated with arrows 172 in the free magnetic layer 130 pointing from left to right and with arrows 174 in the fixed magnetic layer 150 aligned in opposition pointing from right to left. FIG. 2b illustrates a low resistive state, wherein direction of magnetization in the free magnetic layer 130 and the fixed magnetic layer 150 are substantially aligned or parallel with one another. This is illustrated with arrows 172 in the free magnetic layer 130 and with arrows 174 in the fixed magnetic layer 150 aligned the same direction pointing from right to left.

It is understood that the terms “low” and “high” with regard to the resistive state of the magnetic tunnel junction 170 are relative to one another. In other words, the high resistive state is merely a detectibly higher resistance than the low resistive state, and vice versa. Thus, with a detectible difference in resistance, the low and high resistive states can represent different bits of information (i.e. a “0” or a “1”).

The direction of magnetization in the free magnetic layer 130 may be switched through a process call spin transfer torque (“STT”) using a spin-polarized current. An electrical current is generally unpolarized (e.g. consisting of about 50% spin-up and about 50% spin-down electrons). A spin polarized current is one with a great number of electrons of either spin-up or spin-down, which may be generated by passing a current through the fixed magnetic layer 150. The electrons of the spin polarized current from the fixed magnetic layer 150 tunnel through the tunneling barrier layer 140 and transfers its spin angular momentum to the free magnetic layer 130, wherein to free magnetic layer 130 will orient its magnetic direction from anti-parallel, as shown in FIG. 2a, to that of the fixed magnetic layer 150 or parallel, as shown in FIG. 2b. The free magnetic layer 130 may be returned to its origin orientation, shown in FIG. 2a, by reversing the current.

Thus, the magnetic tunneling junction 170 may store a single bit of information (“0” or “1”) by its state of magnetization. The information stored in the magnetic tunneling junction 170 is sensed by driving a current through the magnetic tunneling junction 170. The free magnetic layer 130 does not require power to retain its magnetic orientations; thus, the state of the magnetic tunneling junction 170 is preserved when power to the device is removed. Therefore, the spin transfer torque memory device 100 of FIGS. 1a and 1b is non-volatile.

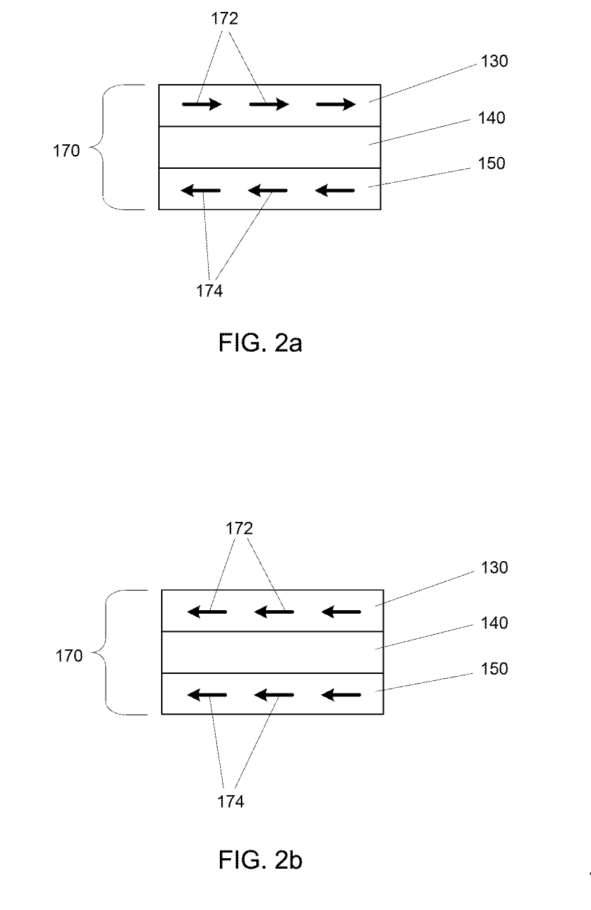

FIG. 3 illustrated an oblique schematic of a specific spin transfer torque memory device 175. In one embodiment, the free magnetic layer electrode 120 and the fixed magnetic layer electrode 160 may comprise any appropriate conductive material or layers of conductive materials, including but not limited to ruthenium, tantalum, titanium, and the like, as well as alloys thereof. The free magnetic layer 130 may comprise at least one ferromagnetic layer, including but not limited to cobalt/iron alloys, nickel/iron alloys, platinum/iron alloys, and the like, which are able to hold a magnetic field or polarization. In a specific embodiment, the free magnetic layer 130 may comprise a cobalt/iron/boron alloy. As shown, at least one additional material layer 125, such as layer of tantalum/hafnium or the like, may be disposed between the free magnetic layer electrode 120 and the free magnetic layer 130 for improved performance, as will be understood to those skilled in the art. In an embodiment, the tunneling barrier layer 140 may be an oxide layer, including but not limited to magnesium oxide (MgO), aluminum oxide (Al₂O₃), and the like.

As further shown in FIG. 3, the fixed magnetic layer 150 may comprise a synthetic anti-ferromagnetic portion 152 and an anti-ferromagnetic layer 154. The synthetic anti-ferromagnetic portion may comprise a first fixed magnetic layer 152₁ abutting the tunneling barrier layer 140, a non-magnetic metal layer 152₂ abutting the first fixed magnetic layer 152₁, and a second fixed magnetic layer 152₃ abutting the non-magnetic metal layer 152₂, wherein the anti-ferromagnetic layer 154 abuts second fixed magnetic layer 152₃. The first fixed magnetic layer 152₁ may comprise an alloy of cobalt, iron, and boron, the non-magnetic metal layer 152₂ may comprise ruthenium or copper, the second fixed magnetic layer 152₃ may comprise a cobalt/iron alloy, and the anti-ferromagnetic layer 154 may comprise platinum/manganese alloy, iridium/manganese alloy, and the like.

However, as previously discussed the spin transfer torque memory device 175 of FIG. 3 may suffer from low speed with high switching current operation. One of the ways to improve performance is through the use of perpendicular magnetic anisotropy (PMA) layers. For materials stacks with high tunnel magnetoresistance, the thickness of the magnetic layer being limited to less than 1.2 nanometers due to the need for surface perpendicular magnetic anisotropy. Therefore, large magnet areas are required to ensure magnetic bit stability at such small magnetic layer thicknesses, as will be understood to those skilled in the art.

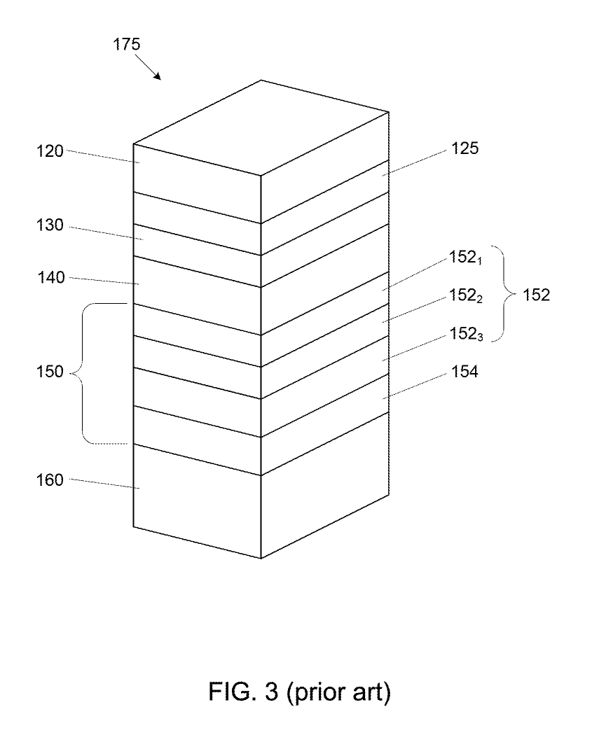

FIG. 4 illustrates a spin transfer torque memory device 180 having a strained, free magnetic layer stack 182 comprising a crystalline magnetic layer 184 and crystalline stressor layer 186, which forms a strain engineered interface 188 therebetween. The crystalline magnetic layer 184 may form a plane in the x-y directions (x-y plane), wherein the strain engineered interface 188 may induce a strong perpendicular magnetic anisotropy 190 in the crystalline magnetic layer 184 pointing out (z-direction) of its plane (x-y plane), such that the spin switching of the crystalline magnetic layer 184 may occur at a higher speed. Both the crystalline magnetic layer 184 and the crystalline stressor layer 186 must be crystalline materials, such as crystalline metals, for the formation of the strain engineered interface 188. In one embodiment of the present description, the crystalline magnetic layer 184 may include any appropriate crystalline magnetic material, including but not limited to, nickel, iron, and cobalt. In a specific embodiment of the present description, the crystalline magnetic layer 184 may comprise a face-centered tetragonal [001] nickel layer. In an embodiment of the present description, the crystalline stressor layer 186 may be any appropriate crystalline material which will induce a strain on the crystalline magnetic layer 184 to form the strain engineered interface 188, including, but not limited to, copper, aluminum, tantalum, tungsten, and the like. In a specific embodiment of the present description, the crystalline stressor layer 186 may comprise a face-centered cubic [001] copper layer.

It is known in the art, the strain engineered interface 188 of a face-centered cubic copper layer having a [001] orientation in direct contact with a face-centered tetragonal [001] nickel layer can produce a strain of +2.5% in the x-y plane and a −3.2% the z-direction (i.e. out of the x-y plane). It is further known that the maximum stress in the z-direction reaches a maximum at about 12 atomic layers of face-centered tetragonal [001] nickel layers which corresponds to 0.76 MA/m³ (i.e. 1.5T anisotropy field).

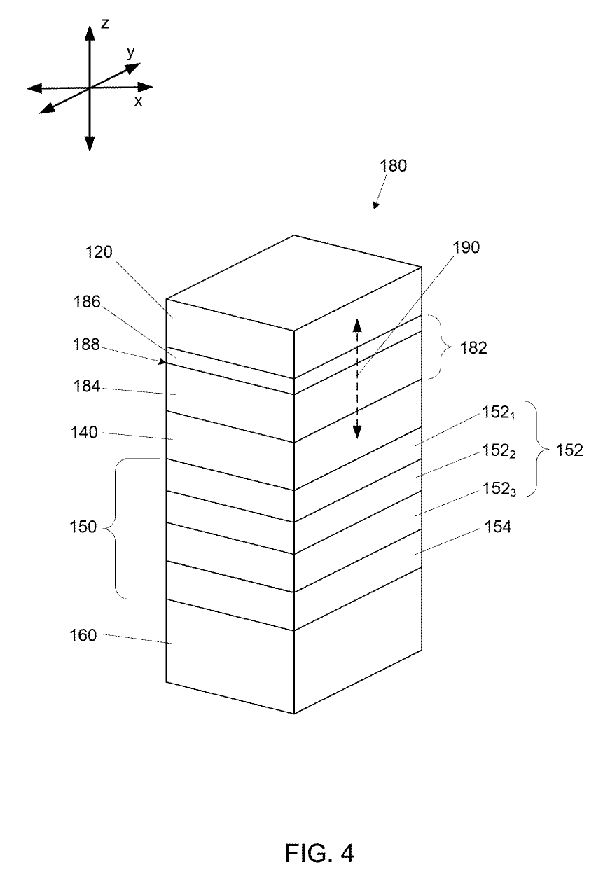

It is understood that although FIG. 4 illustrates the stressor layer 186 being positioned between the free magnetic layer electrode 120 and the crystalline magnetic layer 184, it is understood that the positioning may be reversed wherein the crystalline stressor layer 186 is positioned between the tunneling barrier layer 140 and the crystalline magnetic layer 184, as shown in FIG. 5.

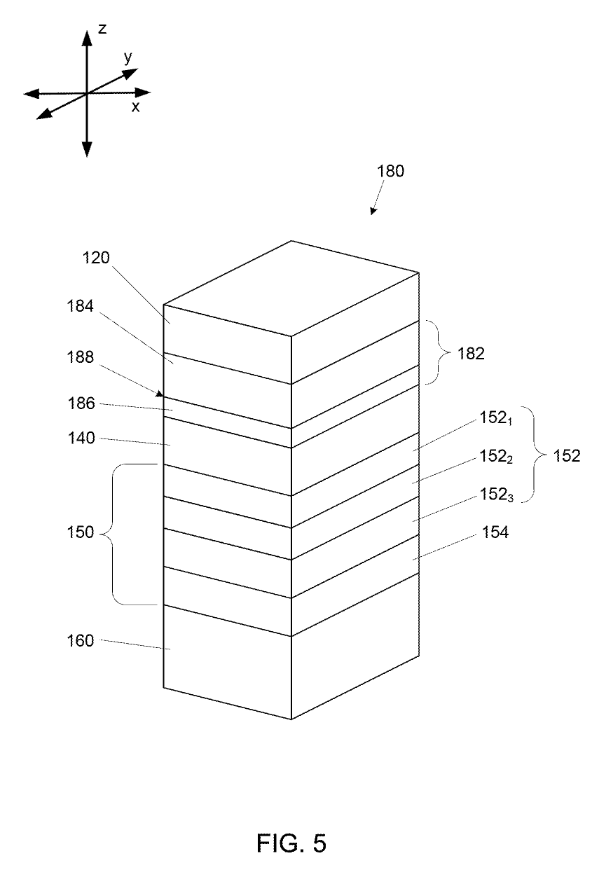

As shown in FIG. 6, the strained, free magnetic layer stack 182 may comprise a plurality of alternating crystalline magnetic layers (illustrated as elements 184₁ and 184₂) and crystalline stressor layers (illustrated as elements 186₁ and 186₂) forming a plurality of strain engineered interfaces (illustrated as elements 188₁ and 188₂). It is understood that the plurality of crystalline magnetic layers 184₁ and 184₂, and the crystalline stressor layers 186₁ and 186₂ may be in a reverse positions, as described with regard to FIG. 5.

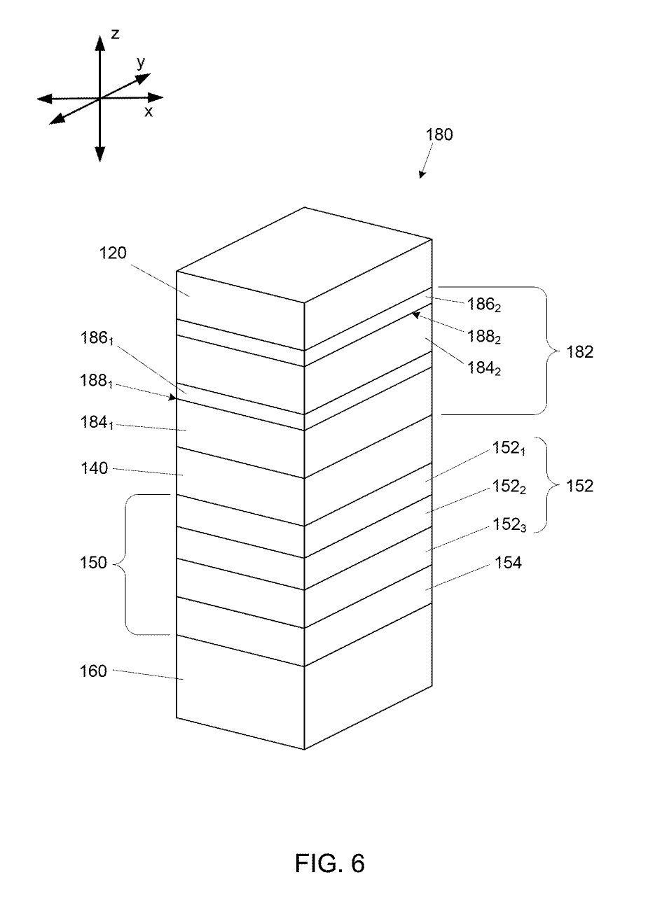

FIG. 7 is a normalize graph of predicted data regarding the performance of the spin transfer torque memory device 175 of FIG. 3 (curve B) versus the spin transfer torque memory device 180 of FIG. 4 (curve A), wherein the X-axis is spin current in micro-amps and the Y-axis is switching time in nanoseconds (log scale). It is predicted that the spin transfer torque memory device 180 of FIG. 4 (curve A) may have approximate three (3) times faster switching speed at the value of current than the spin transfer torque memory device 175 of FIG. 3 (curve B). Further, it is predicted that there may be a nine (9) times improvement in magnet size, wherein a magnet planar size of about 13 nm×13 nm for the spin transfer torque memory device 180 of FIG. 4 would have the same perform as a magnet planar size of about 40 nm×40 nm for the spin transfer torque memory device 175 of FIG. 3. It is also noted that the increased uni-axial anisotropy (Hₖ) also decreases the write error rate of a magnetic tunnel junction to meet the design requirements for embedded application, as will be understood to those skilled in the art.

As will be understood to those skilled in the art, numerous advantages may be realized with the embodiments of the present description, including but not limited to reduction in critical current for a given magnetic thermal barrier, improved stability for a given footprint, and the enablement of significantly thicker free layers (e.g. up to 5 nm for a single face-centered cubic [001] copper layer/face-centered tetragonal [001] nickel layer stack and 5-20 nm for multiple face-centered cubic [001] copper layer/face-centered tetragonal [001] nickel layer stacks.

Embodiments of the present description may have specific stacked arrangements (wherein the “/” indicate what layers abut one another) including but not limited to the following and variations thereof:
1) top electrode/tantalum layer/[face-centered cubic [001] copper layer/face-centered tetragonal [001] nickel layer]ₙ (wherein n is the number of alternating layers pairs, as previously discussed)/CoₓFe_{y}B_{z} layer/magnesium oxide layer/CoₓFe_{y}B_{z} layer/ruthenium layer/CoFe layer/antiferromagnet layering/bottom electrode; and
2) top electrode/antiferromagnet layering/CoFe layer/ruthenium layer/CoₓFe_{y}B_{z} layer/magnesium oxide layer/CoₓFe_{y}B_{z} layer/[face-centered cubic [001] copper layer/face-centered tetragonal [001] nickel layer]ₙ. (wherein n is the number of alternating layer pairs, as previously discussed)/seed layer/bottom electrode.

The presence of layer between the nickel layer and the magnesium oxide (MgO) layer may allow for high magnetoresistance due to the symmetry filtering of the CoₓFe_{y}B_{z}/MgO/CoₓFe_{y}B_{z} system. In the present description, the use of and Ni/CoₓFe_{y}B_{z}/MgO stack may retain a high magnetoresistance while using the magnetic properties of strain induced perpendicular magnetic anisotropy in the nickel layer. Furthermore, in one embodiment of the present description, the thickness of the nickel layer (typically greater than 2 nm) may be engineered to allow for the formation of perpendicular magnetic anisotropy by accumulation of sufficient strain in perpendicular magnetic anisotropy layer (e.g. the nickel layer).

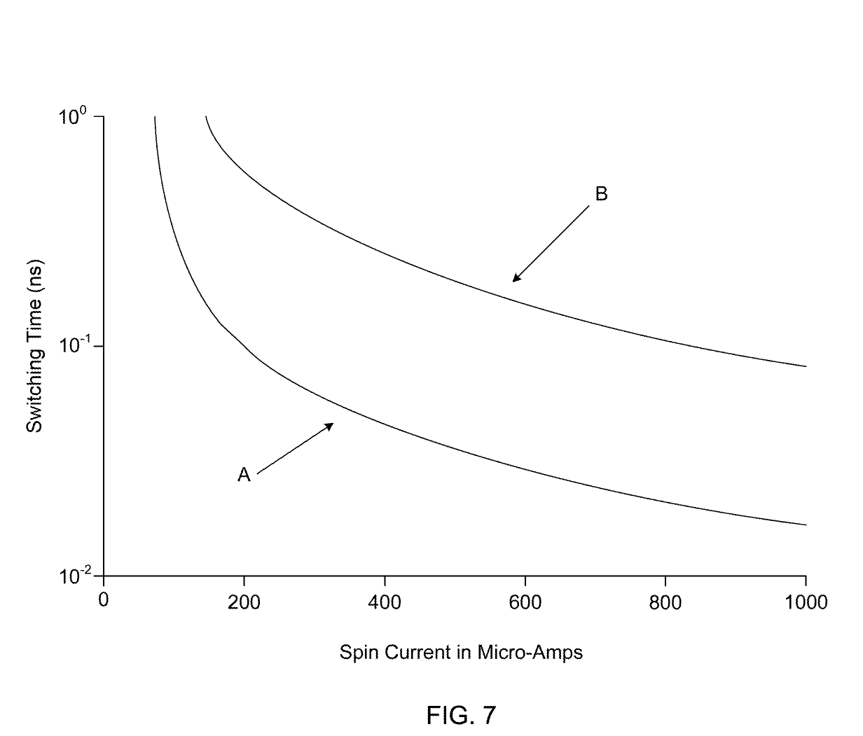

It is known that spin transfer technology may be applied to logic devices. As shown in FIG. 8, a spin logic device 210, as known in the art, may comprise a first or input magnet 212, a second or output magnet 214, and a spin-coherent channel 216 may extend between the input magnet 212 and the output magnet 214, wherein the spin-coherent channel 216 may conduct a spin current (shown as dashed arrow 218) from the input magnet 212 to the output magnet 214 to determine a state of the output magnet in response to the state of the input magnet 212. As the operation of such a spin logic device 210 is known to those skilled in the art, for the sake of brevity and conciseness, the specific principles of operation will not be described herein.

In one known embodiment, the input magnet 212 and/or the output magnet 214 may comprise at least one cobalt/iron/boron alloy magnet, and the spin-coherent channel 216 may be copper. A supply voltage plane 222 may be in electrical communication with both the input magnet 212 and the output magnet 214. The spin-coherent channel 216 may be formed on a dielectric layer 224 and may be electrically connected to a ground plane 226 through a conductive via 228 extending through the dielectric layer 224. At least one dielectric gap 232 may be formed in the spin-coherent channel 216 to provide isolation for the specific device defined by the input magnet 212, the output magnet 214, and spin-coherent channel 216 illustrated.

As will be understood to those skilled in the art, the dimensions of the ground plane 226 may be selected to optimize the energy-delay of the spin logic device 210. As will be further understood to those skilled in the art, the spin-coherent channel 216 may be a wire etched in a copper layer for long spin diffusion length. Furthermore, the directionality of spin logic device 210 may be set by geometric asymmetry between the input magnet 212 and the output magnet 214. The “area of overlap” 234 of the input magnet 212 with the spin-coherent channel 216 may be larger than the “area of overlap” 236 of the output magnet 214, causing asymmetric spin conduction, where the input magnet 212 sets up the direction of the spin in the spin-coherent channel 216. It is understood that the input magnet area of overlap 234 and output magnet area of overlap 236 includes not only a “length” dimension (not labeled) along the plane of the illustrated view, but also a “width” dimension (not shown) extending perpendicularly out of the plane of the illustrated view.

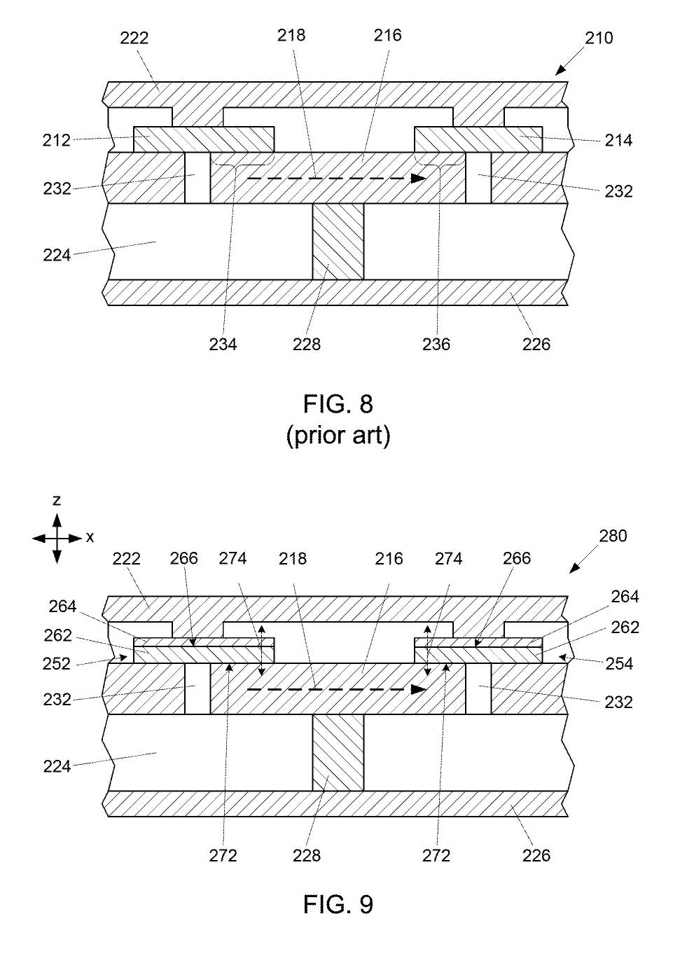

FIG. 9 illustrates one embodiment of the present description, wherein a strained spin logic device 280 may be fabricated by forming an input magnet 252 and an output magnet 254 wherein at least one the input magnet 252 and the output magnet 254 may comprise a crystalline magnetic layer 262 and crystalline stressor layer 264, wherein a strain engineered interface 266 is formed between the crystalline magnetic layer 262 and crystalline stressor layer 264 of the at least one input magnet 252 and output magnet 254. In another embodiment, the spin-coherent channel 216 may comprise a crystalline layer, such that a stain engineer interface 272 is formed between the crystalline magnetic layer 262 and the crystalline spin-coherent channel 216. This may obviate the need for the crystalline stressor layer 264. The crystalline magnetic layer 262 of the at least one of the input magnet 252 and the output magnet 254 may form a plane (x-y direction, where the y direction (not shown) extends perpendicular to the drawing), wherein the strain engineered interface 266 (between the crystalline magnetic layer 262 and the crystalline stressor layer 264) and/or the strain engineered interface 272 (between the crystalline magnetic layer 262 and the crystalline spin-coherent channel 216) may induce a strong perpendicular magnetic anisotropy 274 in the crystalline magnetic layer 262 of the at least one of the input magnet 252 and the output magnet 254 pointing out (z-direction) of its respective plane, such that the spin switching of at least one of the input magnet 252 and the output magnet 254 may occur at a higher speed. In one embodiment of the present description, the crystalline magnetic layer 262 of at least one of the input magnet 252 and the output magnet 254 may include any appropriate crystalline magnetic material, including but not limited to, nickel, iron, and cobalt. In a specific embodiment of the present description, the crystalline magnetic layer 262 of at least one of the input magnet 252 and the output magnet 254 may comprise a face-centered tetragonal [001] nickel layer. In an embodiment of the present description, at least one of the crystalline stressor layer 264 and spin-coherent channel 216 may be any appropriate crystalline material which will induce a strain on the crystalline magnetic layer 262 to form the strain engineered interface 266 (between the crystalline magnetic layer 262 and the crystalline stressor layer 264) and/or the strain engineered interface 272 (between the crystalline magnetic layer 262 and the crystalline spin-coherent channel 216), including, but not limited to, copper, aluminum, tantalum, tungsten, and the like. In a specific embodiment of the present description, at least one of the crystalline stressor layer 264 and the spin-coherent channel 216 may comprise a face-centered cubic [001] copper layer. The potential benefits of such a strain engineered interface(s) as the strain engineered interface 266 (between the crystalline magnetic layer 262 and the crystalline stressor layer 264) and/or the strain engineered interface 272 (between the crystalline magnetic layer 262 and the crystalline spin-coherent channel 216) have been discussed with regard to the spin transfer torque memory device 180 of FIGS. 4-6, and, for the sake of brevity and conciseness, will not be repeated. It is understood that although FIG. 9 illustrates the stressor layer 264 being positioned over the crystalline magnetic layer 262, it is understood that the positioning may be reversed.

The performance of the known embodiment of FIG. 8 having cobalt/iron/boron alloy magnets and the performance of the embodiment of the present description of FIG. 9 having a strain engineered interfaces 252 resulting from an interface between face-centered cubic [001] copper layers and face-centered tetragonal [001] nickel magnets may be estimated by simulating the transient spin dynamics and transport using vector spin circuit models coupled with magnet dynamics, wherein the magnets may be treated as single magnetic moments and spin circuit theory may be used to calculate the scalar voltage and vector spin voltages. The dynamics of the magnets may be described by Landau-Lifshitz-Gilbert equations, as follows:

δm₁/δt=−γμ₀[m₁*H_{eff}]+α[m₁*δm₁/δt]+Iₛ₁/eNₛ

δm₂/δt=−γμ₀[m₂*H_{eff}]+α[m₂*δm₂/δt]+Iₛ₂/eNₛ

wherein: m₁ and m₂ are input magnets and output magnets, respectively
t is time
γ is the electron gyromagnetic ratio
μ₀ is the magnetic permeability of vacuum
H_{eff} is the effective magnetic field originating from the shape and material anisotropy
α is the Gilbert damping constant
Iₛ₁ and Iₛ₂ are the projections perpendicular to magnetizations of the spin polarized currents entering the magnets derived from spin-circuit analysis
e is electron charge
Nₛ is the number of spins
   The spin equivalent circuit comprises the tensor spin conduction matrix determined by the instantaneous direction of magnetization and a self-consistent stochastic solver is used to account for thermal noise of the magnets.

The results of such a simulation are summarized in Table 1, wherein a three-fold improvement in switching time and energy/bit is expected.

TABLE 1

| | |
|---|---|
| FIG. 7 (Co/Fe/B) | FIG. 8 (Ni/Cu) |

| | | | | |
|---|---|---|---|---|
| Switching Time | ~0.6 | ns | 0.2 | ns |
| Energy/Bit | 7.1 | fJ | 2.5 | fJ |
| Energy*Delay | 4.2 | fJ*ns | 0.5 | fJ*ns |

Although the precise methods of fabricating the strained spin transfer torque memory device 180 of FIGS. 4-6 or the strained spin logic device 250 of FIG. 9 has not been described herein, it is understood that the steps for fabrication may include standard microelectronic fabrication processes such as lithography, etch, thin films deposition, planarization (such as chemical mechanical polishing (CMP)), diffusion, metrology, the use of sacrificial layers, the use of etch stop layers, the use of planarization stop layers, and/or any other associated action with microelectronic component fabrication.

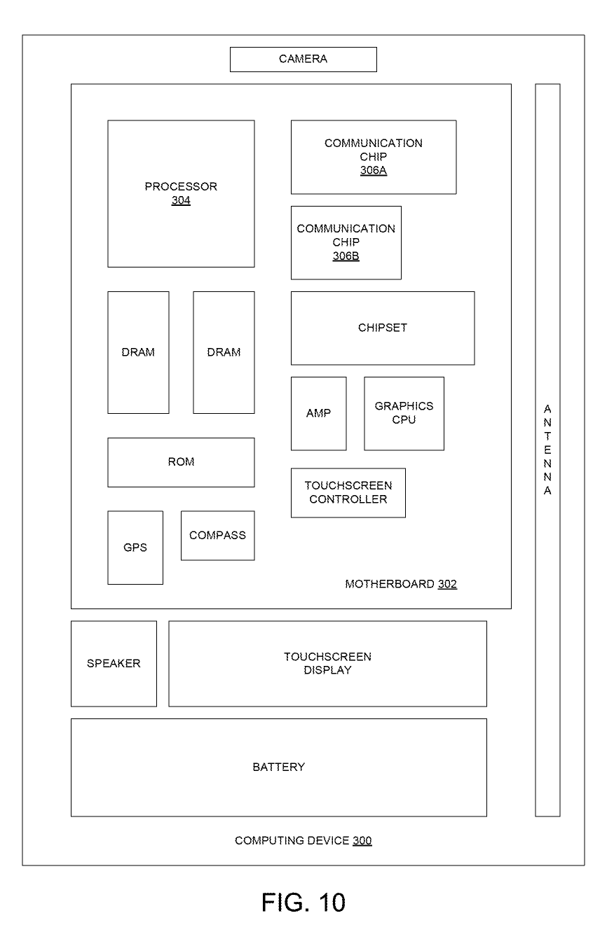

FIG. 10 illustrates a computing device 300 in accordance with one implementation of the present description. The computing device 300 houses a board 302. The board 302 may include a number of components, including but not limited to a processor 304 and at least one communication chip 306A, 306B. The processor 304 is physically and electrically coupled to the board 302. In some implementations the at least one communication chip 306A, 306B is also physically and electrically coupled to the board 302. In further implementations, the communication chip 306A, 306B is part of the processor 304.

Depending on its applications, the computing device 300 may include other components that may or may not be physically and electrically coupled to the board 302. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 306A, 306B enables wireless communications for the transfer of data to and from the computing device 300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 306 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 300 may include a plurality of communication chips 306A, 306B. For instance, a first communication chip 306A may be dedicated to shorter range wireless communications such as Wi-Fi and Bluetooth and a second communication chip 306B may be dedicated to longer range wireless communications such as GPS, EDGE, GPRS, CDMA, WiMAX, LTE, Ev-DO, and others.

The processor 304 of the computing device 300 may include at least one strained spin logic device and/or strained spin transfer torque memory device, as described above. The term “processor” may refer to any device or portion of a device that processes electronic data from registers and/or memory to transform that electronic data into other electronic data that may be stored in registers and/or memory. Furthermore, the communication chip 306A, 306B may include at least one strained spin logic device and/or strained spin transfer torque memory device, as described above.

In various implementations, the computing device 300 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 300 may be any other electronic device that processes data.

It is understood that the subject matter of the present description is not necessarily limited to specific applications illustrated in the figures. The subject matter may be applied to other microelectronic device and assembly applications, as well as any appropriate transistor application, as will be understood to those skilled in the art.

The following examples pertain to further embodiments, wherein Example 1 is a spin transfer torque memory device including a free magnetic layer stack comprising a crystalline magnetic layer abutting a crystalline stressor layer; a fixed magnetic layer; and a tunneling barrier layer disposed between the free magnetic layer stack and the fixed magnetic layer.

In Example 2, the subject matter of Example 1 can optionally include the crystalline magnetic layer being planar and further including magnetic anisotropy perpendicular to the planar crystalline magnetic layer.

In Example 3, the subject matter of any of Examples 1 to 2 can optionally include the crystalline magnetic layer being selected from the group of materials consisting of nickel, iron, and cobalt.

In Example 4, the subject matter of any of Examples 1 to 2 can optionally include the crystalline magnetic layer comprises a face-centered tetragonal [001] nickel layer.

In Example 5, the subject matter of any of Examples 1 to 4 can optionally include the crystalline stressor layer is selected from the group of materials consisting of copper, aluminum, tantalum, and tungsten.

In Example 6, the subject matter of any of Examples 1 to 4 can optionally include the crystalline stressor layer comprises a face-centered cubic [001] copper layer.

In Example 7, the subject matter of any of Examples 1 to 6 can optionally include a fixed magnetic layer electrode electrically connected to a bit line, wherein the fixed magnetic layer is adjacent the fixed magnetic layer electrode; a free magnetic layer electrode adjacent the free magnetic layer stack; and a transistor electrically connected to the free magnetic layer electrode, a source line, and a word line.

In Example 8, the subject matter of any of Examples 1 to 6 can optionally include a fixed magnetic layer electrode adjacent the fixed magnetic layer; a free magnetic layer electrode adjacent the free magnetic layer and electrically connected to a bit line; and a transistor electrically connected to the fixed magnetic layer electrode, a source line, and a word line.

The following examples pertain to further embodiments, wherein Example 9 is a spin logic device comprising an input magnet; an output magnet; wherein at least one of the input magnet and the output magnet comprises a magnet stack including a crystalline magnetic layer abutting a crystalline stressor layer; and a spin-coherent channel extending between the input magnet and the output magnet.

In Example 10, the subject matter of Example 9 can optionally include the crystalline magnetic layer of the at least one of the input magnet and the output magnet being planar and further including magnetic anisotropy perpendicular to the crystalline magnetic layer of the at least one planar input magnet and the planar output magnet.

In Example 11, the subject matter of any of Examples 9 to 10 can optionally include the crystalline magnetic layer of the at least one of the input magnet and the output magnet being selected from the group of materials consisting of nickel, iron, and cobalt.

In Example 12, the subject matter of any of Examples 9 to 10 can optionally include the crystalline magnetic layer of the at least one of the input magnet and the output magnet comprising a face-centered tetragonal [001] nickel layer.

In Example 13, the subject matter of any of Examples 9 to 12 can optionally include the crystalline stressor layer of the at least one of the input magnet and the output magnet being selected from the group of materials consisting of copper, aluminum, tantalum, and tungsten.

In Example 14, the subject matter of any of Examples 9 to 12 can optionally include the crystalline stressor layer of the at least one of the input magnet and the output magnet comprising a face-centered cubic [001] copper layer.

The following examples pertain to further embodiments, wherein Example 15 is a spin logic device comprising an input magnet, an output magnet, a crystalline spin-coherent channel extending between the input magnet and the output magnet, wherein at least one of the input magnet and the output magnet comprises a crystalline magnetic layer abutting the crystalline spin-coherent channel.

In Example 16, the subject matter of Example 15 can optionally include the crystalline magnetic layer of the at least one of the input magnet and the output magnet being planar and further including magnetic anisotropy perpendicular to the crystalline magnetic layer of the at least one planar input magnet and the planar output magnet.

In Example 17, the subject matter of any of Examples 15 to 16 can optionally include the crystalline magnetic layer of the at least one of the input magnet and the output magnet is selected from the group of materials consisting of nickel, iron, and cobalt.

In Example 18, the subject matter of any of Examples 15 to 16 can optionally include the crystalline magnetic layer of the at least one of the input magnet and the output magnet comprising a face-centered tetragonal [001] nickel layer.

In Example 19, the subject matter of any of Examples 15 to 18 can optionally include the crystalline spin-coherent channel being selected from the group of materials consisting of copper, aluminum, tantalum, and tungsten.

In Example 20, the subject matter of any of Examples 15 to 18 can optionally include the crystalline spin-coherent channel comprising a face-centered cubic [001] copper layer.

The following examples pertain to further embodiments, wherein Example 21 is an electronic system, comprising a board; and a microelectronic device attached to the board, wherein the microelectronic device includes at least one of a spin transfer torque memory device and a spin logic device; wherein the spin transfer torque memory device includes a free magnetic layer stack comprising a crystalline magnetic layer abutting a crystalline stressor layer, a fixed magnetic layer, and a tunneling barrier layer disposed between the free magnetic layer stack and the fixed magnetic layer; wherein the spin logic device includes at least one of: an input magnet, an output magnet; wherein at least one of the input magnet and the output magnet comprises a magnet stack including a crystalline magnetic layer abutting a crystalline stressor layer; and a spin-coherent channel extending between the input magnet and the output magnet; and an input magnet, an output magnet, a crystalline spin-coherent channel extending between the input magnet and the output magnet, wherein at least one of the input magnet and the output magnet comprises a crystalline magnetic layer abutting the crystalline spin-coherent channel.

In Example 22, the subject matter of Example 21 can optionally include the crystalline magnetic layer of the spin transfer torque memory device and/or the crystalline magnetic layer of the at least one input magnet and output magnet of the spin logic device comprising a face-centered tetragonal [001] nickel layer.

In Example 23, the subject matter of any of Examples 21 to 22 can optionally include the crystalline stressor layer of the spin transfer torque memory device and/or of the spin logic device comprising a face-centered cubic [001] copper layer.

In Example 24, the subject matter of any of Examples 21 to 23 can optionally include the crystalline spin-coherent channel of the spin logic device comprising a face-centered cubic [000] copper layer.

Having thus described in detail embodiments of the present description, it is understood that the present description defined by the appended claims is not to be limited by particular details set forth in the above description, as many apparent variations thereof are possible without departing from the spirit or scope thereof.

1. A spin transfer torque memory device, comprising:
a free magnetic layer stack comprising a crystalline magnetic layer abutting a crystalline stressor layer;
a fixed magnetic layer; and
a tunneling barrier layer disposed between the free magnetic layer stack and the fixed magnetic layer.

2. The spin transfer torque memory device of claim 1, wherein the crystalline magnetic layer is planar and further including magnetic anisotropy perpendicular to the planar crystalline magnetic layer.

3. The spin transfer torque memory device of claim 1, wherein the crystalline magnetic layer is selected from the group of materials consisting of nickel, iron, and cobalt.

4. The spin transfer torque memory device of claim 1, wherein the crystalline magnetic layer comprises a face-centered tetragonal [001] nickel layer.

5. The spin transfer torque memory device of claim 1, wherein the crystalline stressor layer is selected from the group of materials consisting of copper, aluminum, tantalum, and tungsten.

6. The spin transfer torque memory device of claim 1, wherein the crystalline stressor layer comprises a face-centered cubic [001] copper layer.

7. The spin transfer torque memory device of claim 1, further comprising:
a fixed magnetic layer electrode electrically connected to a bit line, wherein the fixed magnetic layer is adjacent the fixed magnetic layer electrode;
a free magnetic layer electrode adjacent the free magnetic layer stack; and
a transistor electrically connected to the free magnetic layer electrode, a source line, and a word line.

8. The spin transfer torque memory device of claim 1, further comprising:
a fixed magnetic layer electrode adjacent the fixed magnetic layer;
a free magnetic layer electrode adjacent the free magnetic layer and electrically connected to a bit line; and
a transistor electrically connected to the fixed magnetic layer electrode, a source line, and a word line.

9. A spin logic device comprising:
an input magnet;
an output magnet;
wherein at least one of the input magnet and the output magnet comprises a magnet stack including a crystalline magnetic layer abutting a crystalline stressor layer; and
a spin-coherent channel extending between the input magnet and the output magnet.

10. The spin logic device of claim 9, wherein the crystalline magnetic layer of the at least one of the input magnet and the output magnet is planar and further including magnetic anisotropy perpendicular to the crystalline magnetic layer of the at least one planar input magnet and the planar output magnet.

11. The spin logic device of claim 9, wherein the crystalline magnetic layer of the at least one of the input magnet and the output magnet is selected from the group of materials consisting of nickel, iron, and cobalt.

12. The spin logic device of claim 9, wherein the crystalline magnetic layer of the at least one of the input magnet and the output magnet comprises a face-centered tetragonal [001] nickel layer.

13. The spin logic device of claim 9, wherein the crystalline stressor layer of the at least one of the input magnet and the output magnet is selected from the group of materials consisting of copper, aluminum, tantalum, and tungsten.

14. The spin logic device of claim 9, wherein the crystalline stressor layer of the at least one of the input magnet and the output magnet comprises a face-centered cubic [001] copper layer.

15. A spin logic device comprising:
an input magnet;
an output magnet;
a crystalline spin-coherent channel extending between the input magnet and the output magnet; and
wherein at least one of the input magnet and the output magnet comprises a crystalline magnetic layer abutting the crystalline spin-coherent channel.

16. The spin logic device of claim 15, wherein the crystalline magnetic layer of the at least one of the input magnet and the output magnet is planar and further including magnetic anisotropy perpendicular to the crystalline magnetic layer of the at least one planar input magnet and the planar output magnet.

17. The spin logic device of claim 15, wherein the crystalline magnetic layer of the at least one of the input magnet and the output magnet is selected from the group of materials consisting of nickel, iron, and cobalt.

18. The spin logic device of claim 15, wherein the crystalline magnetic layer of the at least one of the input magnet and the output magnet comprises a face-centered tetragonal [001] nickel layer.

19. The spin logic device of claim 15, wherein the crystalline spin-coherent channel is selected from the group of materials consisting of copper, aluminum, tantalum, and tungsten.

20. The spin logic device of claim 15, wherein the crystalline spin-coherent channel comprises a face-centered cubic [001] copper layer.

21. An electronic system, comprising:
a board; and
a microelectronic device attached to the board, wherein the microelectronic device includes at least one of a spin transfer torque memory device and a spin logic device;
wherein the spin transfer torque memory device includes a free magnetic layer stack comprising a crystalline magnetic layer abutting a crystalline stressor layer, a fixed magnetic layer, and a tunneling barrier layer disposed between the free magnetic layer stack and the fixed magnetic layer;
wherein the spin logic device includes at least one of:
an input magnet, an output magnet; wherein at least one of the input magnet and the output magnet comprises a magnet stack including a crystalline magnetic layer abutting a crystalline stressor layer; and a spin-coherent channel extending between the input magnet and the output magnet; and
an input magnet, an output magnet, a crystalline spin-coherent channel extending between the input magnet and the output magnet, wherein at least one of the input magnet and the output magnet comprises a crystalline magnetic layer abutting the crystalline spin-coherent channel.

22. The electronic system of claim 21, wherein the crystalline magnetic layer of the spin transfer torque memory device and/or the crystalline magnetic layer of the at least one input magnet and output magnet of the spin logic device comprises a face-centered tetragonal [001] nickel layer.

23. The electronic system of claim 21, wherein the crystalline stressor layer of the spin transfer torque memory device and/or of the spin logic device comprises a face-centered cubic [001] copper layer.

24. The electronic system of claim 21, wherein the crystalline spin-coherent channel of the spin logic device comprises a face-centered cubic [001] copper layer.
